(19) United States
(12) Patent Application Publication
(10) Pub. No.: US 2009/0146723 A1
(43) Pub. Date: Jun. 11, 2009

(54) BUFFER CIRCUIT

(75) Inventor: Katsuji KIMURA, Nakahara-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Nakahara-ku (JP)

(21) Appl. No.: 12/330,643

(22) Filed: Dec. 9, 2008

(30) Foreign Application Priority Data
Dec. 11, 2007 (JP) 2007-319763

(51) Int. Cl. H03L 5/00

(52) U.S. Cl. 327/333

(57) ABSTRACT

Disclosed is a buffer circuit including a source follower circuit comprising a MOS transistor which is driven by a current source. The MOS transistor has a gate to which an input voltage is supplied, a source from which an output voltage is output and a back gate supplied with a back gate voltage for being controlled to provide for a desired value of the source voltage. There is provided a second MOS transistor, to a gate of which a bias voltage is supplied, and a source of which is connected to a non-inverting input terminal of an OP amp. An output voltage of the OP amp is supplied as the back gate voltage

### REFERENCE TO RELATED APPLICATION

This application is based upon and claims the benefit of the priority of Japanese patent application No. 2007-319763, filed on Dec. 11, 2007, the disclosure of which is incorporated herein in its entirety by reference thereto.

### FIELD OF THE INVENTION

This invention relates to a buffer circuit. More particularly, it relate to a buffer circuit including a source follower circuit having a constant output operating voltage, that is, a constant value of level shifting, and which may be suited to be formed on a semiconductor integrated circuit.

### BACKGROUND OF THE INVENTION

As this sort of the buffer circuit, such a circuit employing a source follower circuit is used. In FIG. 1, a circuit diagram showing an example of the typical configuration of a buffer circuit employing a source follower circuit. There is naturally raised a demand for making an amount of level shifting in the source follower circuit constant. A d.c. voltage of an input signal is cut off by a capacitor C, and a preset voltage may then be applied to the gate of a source follower transistor M1 to set a d.c. operating point of the source follower circuit to a preset value. However, since an a.c. signal is contained in an output of the source follower circuit, it is necessary to remove this a.c. signal in order to obtain a d.c. operating point.

If a source follower buffer circuit is to be formed in an integrated circuit, such a method in which there is provided another source follower circuit of the same type not supplied with the input signal, and its output voltage is used, is adopted in preference to the technique of removing the a.c. signal from the output of the source follower circuit. The source follower circuit added is called a ‘replica circuit’. The reason of using the replica source follower is that in an integrated circuit, the same characteristics may be realized with the same circuits formed on the same chip.

A drain current ID of a MOS transistor is expressed by

I_{D}=β(V_{GS}−V_{TH})² (1)

In the above equation, β is a transconductance parameter of a unit parameter expressed as

$$β = \frac{1}{2} µ ( \frac{ɛ}{{t}_{OX}} ) ( \frac{W}{L} ) \qquad ( 2 )$$

where μ is an electron mobility, ε is a dielectric constant of a gate insulating film, tₒₓ is a film thickness of a gate insulating film, and W, L are gate width and gate length of a unit transistor, respectively.

The amount of level shifting in the source follower circuit is the gate-to-source voltage V_{GS}.

A source operating voltage may thus be set by varying a bias voltage applied to the gate.

In the source follower circuit, the amount of level shifting may be set to V_{GS} by varying a driving current.

As regards a receiver circuit (buffer circuit), reference may be made to, for example, the disclosure of Patent Document 1.
[Patent Document 1] U.S. Pat. No. 7,126,337 (U.S. Pat. No. 7,126,337B2)

### SUMMARY OF THE DISCLOSURE

The following analysis is made from the side of the present invention.

With the above described buffer circuit, in which the capacitor C is added to the input, it is not possible to transfer a low frequency signal. With the configuration in which the amount of level shifting is set to V_{GS} by varying the driving current, the capacitor C is not connected to the input, and hence the input signal from a low frequency signal may be transmitted. It is however not possible to reduce variations of the circuit current. Thus, the following problems are presented.

The first problem is that a low frequency signal cannot be transmitted because the capacitor C is connected to the input.

The second problem is that the circuit current cannot be decreased because the amount of level shifting is set by varying a driving current.

The third problem is that a power supply voltage cannot be lowered because of variations of the threshold voltage.

The present invention seeks to solve one or more of the above problems.

According to the present invention, there is provided a buffer circuit comprising a source follower circuit including a MOS transistor driven by a current source. The MOS transistor has a gate to which an input voltage is supplied, has a source from which an output voltage is produced, and has a back gate to which a preset back gate voltage is supplied. In the source follower circuit according to the present invention, the source voltage of the MOS transistor may be set to a desired voltage by applying a preset back gate voltage to the MOS transistor. In one embodiment of the present invention, the buffer circuit includes a control circuit that controls the back gate voltage to provide for a desired value of the voltage at a source of the MOS transistor.

In one embodiment of the present invention, the control circuit may include an operational amplifier (OP amp). The back gate voltage is controlled so that the operating voltage at the source of the MOS transistor will be equal to a preset voltage.

In one embodiment of the present invention, the operating voltage at the source is obtained at a source voltage of a second MOS transistor which is substantially equal to the operating voltage of the aforementioned MOS transistor.

According to the present invention, in which an input is directly connected to a transistor without the intermediary of a capacitor, it is possible to transmit a signal inclusive from a low frequency signal (d.c. signal) to a higher frequency.

According to the present invention, in which a driving signal is fixed, it is possible to reduce a current.

According to the present invention, in which a threshold voltage is made constant, it is also possible to implement lower voltage.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIG. 1 is a circuit diagram showing a configuration of a buffer circuit of the related art.

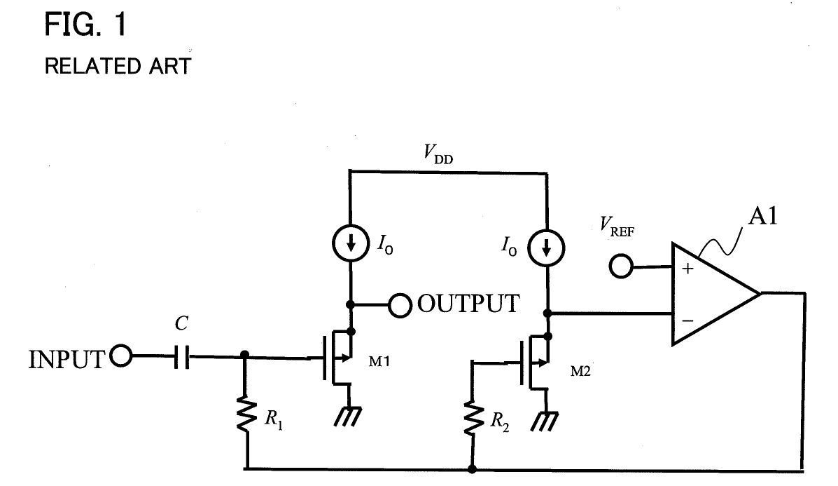

FIG. 2 is a circuit diagram showing a configuration of an exemplary embodiment of the present invention.

FIG. 3 is a circuit diagram showing a configuration of Example 1 of the present invention.

FIG. 4 is a circuit diagram showing a configuration of Example 2 of the present invention.

### PREFERRED MODES OF THE INVENTION

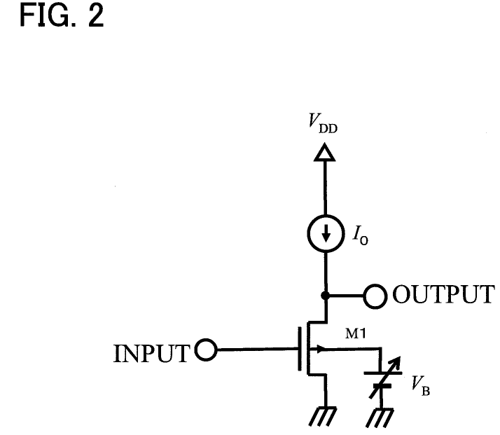

Preferred exemplary embodiments of the present invention are now described with reference to the drawings. FIG. 2 is a circuit diagram showing an exemplary embodiment of a buffer circuit according to the present invention (corresponding to claim 1). The source follower circuit, also termed a ‘voltage follower circuit’, has a voltage gain equal to 1 (0 dB). The voltage follower circuit has a current gain (the current gain being 1 or higher), the loop gain is 1 or higher, and hence oscillation may be produced if a phase rotation should occur in the loop.

A P-channel MOS transistor M1 is a source follower circuit driven by a constant current I₀. It is a voltage follower circuit in which shifting of a voltage level is performed.

Referring to FIG. 2, an input signal INPUT is supplied to a gate of the MOS transistor M1, from a source of which an output signal OUTPUT is output. A voltage V_{B} is supplied to a back gate of the MOS transistor M1. In this case, a drain current I_{D} of the MOS transistor M1 is expressed by the following equation:

I_{D}=β(V_{GS}−V_{TH})²=I₀ (3)

This equation is the same as the equation (1). However, a voltage different from the source voltage (back gate voltage) V_{B} is supplied to the back gate of the MOS transistor M1 operating as the source follower.

It is noted that the threshold voltage V_{TH} of the MOS transistor depends on the back gate voltage and may be expressed by

V_{HT}=V_{TH0}+γ(\sqrt{2|φ_{F}|−V_{BS}}−\sqrt{2|φ_{F}|}) (4)

where V_{TH0} denotes a threshold voltage for the back gate-to-source voltage V_{BS} equal to zero (V_{BS}=0), γ is a bulk threshold parameter and φ_{F} is a strong inversion surface potential.

Hence, the drain current is expressed by

I_{D}=I₀=β{V_{GS}−V_{TH0}−γ(\sqrt{2|φ_{F}|−V_{BS}}−\sqrt{2|φ_{F}|})}² (5)

From the equation (5), the amount of level shifting of the source follower circuit is given by

V_{GS}=\sqrt{Iₒ/β}+V_{TH0}+γ(\sqrt{2|φ_{F}|−V_{BS}}−\sqrt{2|φ_{F}|}) (6)

and may be set by varying the back gate-to-source voltage V_{BS}.

The buffer circuit of the present invention is able to transmit a signal from a low frequency, suffers from only small changes in the circuit current and may well be suited to be formed on a semiconductor integrated circuit.

### EXAMPLE 1

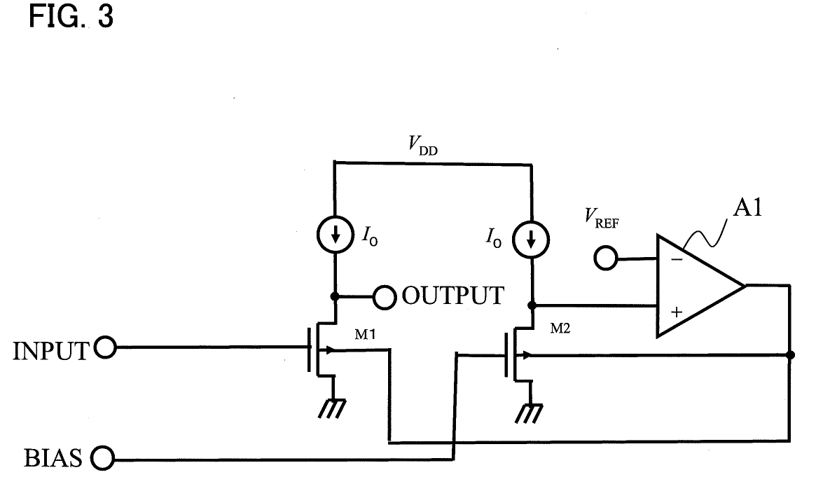

FIG. 3 shows the configuration of an example of a buffer circuit according to the present invention (corresponding to claim 4). Referring to FIG. 3, the buffer circuit includes a first voltage follower transistor (P-channel MOS transistor) M1 and a second voltage follower transistor (P-channel MOS transistor) M2. The first voltage follower transistor M1 receives a signal at its gate and an output signal is produced at its source. The second voltage follower transistor M2 receives a bias voltage BIAS at its gate and has a source connected to a non-inverting input terminal (+) of an OP amp (operational amplifier) A1. Drains of transistors M1 and M2 are connected to GND(ground). The OP amp A1 receives a preset reference voltage V_{REF} at its inverting input terminal (−) and has an output terminal connected in common to respective back gates of the transistors M1 and M2.

The transistor M2 is a replica transistor of the transistor M1. The same bias conditions, that is, the same gate bias voltage and the same constant current sources providing currents to sources are used for the two transistors M1 and M2 so that the two transistors will perform the same operations.

It should be noted that the transistors M1 and M2 are of the same size, and the voltages applied to their back gates are equal to each other. Hence, the threshold voltages V_{TH} of the two transistors are set so as to be equal to each other. The amount of the level shifting of the source follower circuit may thus be given by the above equation (6)

V_{GS}=\sqrt{I₀/β}+V_{TH0}+γ(\sqrt{2|φ_{F}|−V_{BS}}−\sqrt{2|φ_{F}|})

and hence may be set by varying the back gate-to-source voltage V_{BS}.

### EXAMPLE 2

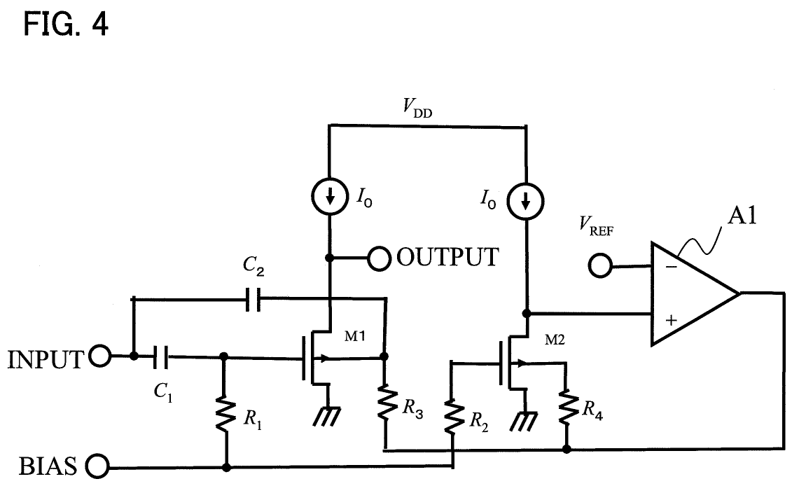

FIG. 4 shows the configuration of a circuit which is an example of the buffer circuit according to the present invention (corresponding to claim 5). If the amplitude of an input signal INPUT increases, an output signal appears at the source of the transistor M1, so that, strictly speaking, there is produced a difference between the back gate-to-source voltage V_{BS} of the transistor M1 and that of the transistor M2.

This buffer circuit includes a first voltage follower transistor (P-channel MOS transistor) M1 and a second voltage follower transistor (P-channel MOS transistor) M2. The input signal INPUT is supplied via a capacitor C1 to the gate of the first voltage follower transistor M1 and via a capacitor C2 to its back gate. A bias voltage BIAS is supplied via a resistor R1 to a gate of the transistor M1, from a source of which an output signal OUTPUT is produced. The bias voltage BIAS is also applied via a resistor R2 to the gate of the second voltage follower transistor M2, a source of which is connected to a non-inverting input terminal (+) of the OP amp A1. A preset voltage V_{REF} is applied to an inverting input terminal (−) of the OP amp A1, an output terminal of which is connected via a resistor R3 to the back gate of the transistor M1, while being connected via a resistor R4 to a back gate of the transistor M2.

Since the transistors M1 and M2 are driven by constant current sources of equal current values I₀, the d.c. bias voltages applied to the two transistors M1 and M2 are equal to each other, such that there is noticed no difference in their operating points.

However, if the amplitude of the input signal INPUT is increased, an output signal OUTPUT will appear at the source of the transistor M1. Thus, strictly speaking, there is caused a difference between the back gate-to-source voltage V_{BS} of the transistor M1 and that of the transistor M2.

It is therefore necessary to set the back gate-to-source voltage V_{BS} of the transistor M1 so as to be substantially equal to the back gate-to-source voltage V_{BS} of the transistor M2.

With the voltage follower circuit, the input and the output are in phase with each other, with the voltage gain being 1. Hence, the amplitude level of the input is equal to that of the output. The signal level supplied to the gate via the capacitor C1 is thus the same as that appearing at a source output terminal, so that, by supplying the input signal via the capacitor C2 to the back gate, the back gate-to-source voltage V_{BS} of the transistor M1 may be made constant even at the time of delivery of the input signal.

The buffer circuit of the present invention may be used as an I/O buffer circuit arranged at an input or at an output mounted on an LSI chip.

According to the present invention, the transistor M1 of the source follower configuration or the replica circuit M2, shown in FIGS. 2 to 4 is not limited to the P-channel MOS transistors, and may, of course, be constituted by N-channel MOS transistors.

The disclosure of the aforementioned Patent Document 1 is incorporated herein by reference. The particular exemplary embodiments or examples may be modified or adjusted within the gamut of the entire disclosure of the present invention, inclusive of claims, based on the fundamental technical concept of the invention. Further, variegated combinations or selection of elements disclosed herein may be made within the framework of the claims. That is, the present invention may encompass various modifications or corrections that may occur to those skilled in the art in accordance with the within the gamut of the entire disclosure of the present invention, inclusive of claim and the technical concept of the present invention.

It should be noted that other objects, features and aspects of the present invention will become apparent in the entire disclosure and that modifications may be done without departing the gist and scope of the present invention as disclosed herein and claimed as appended herewith.

What is claimed is:

1. A buffer circuit comprising a source follower circuit including
a MOS transistor driven by a current source, the MOS transistor having a gate to which an input voltage is supplied, having a source from which an output voltage is produced, and having a back gate to which a preset back gate voltage is supplied.

2. The buffer circuit according to claim 1, further comprising
a circuit that controls the back gate voltage so that a voltage at the source of the MOS transistor is set to a desired value.

3. The buffer circuit according to claim 2, wherein the circuit that controls the back gate voltage includes
an operational amplifier circuit controlling the back gate voltage so that the operating voltage of the source will be substantially equal to a preset voltage.

4. The buffer circuit according to claim 3, further comprising
a second MOS transistor with an operating voltage at a source thereof being substantially equal to that of the MOS transistor, wherein the operating voltage at the source of the source follower circuit is obtained from the source voltage of the second MOS transistor.

5. The buffer circuit according to claim 1, wherein the amount of level shifting in the source follower circuit is set by varying the back gate-to-source voltage of the MOS transistor.

6. The buffer circuit according to claim 4, wherein the operational amplifier circuit has an input terminal pair to which the source voltage of the second MOS transistor and a preset voltage are differentially supplied and has an output terminal commonly connected to the back gate of the MOS transistor and to a back gate of the second MOS transistor.

7. The buffer circuit according to claim 1, further comprising:
a second MOS transistor;
a first current source connected between the source of the MOS transistor and a power supply;
a second current source connected between a source of the second MOS transistor and the power supply,
the MOS transistor and the second MOS transistor having drains thereof grounded, an input signal being applied to the gate of the MOS transistor, a bias voltage being applied to a gate of the second MOS transistor, the source of the MOS transistor being used as an output node of the buffer circuit; and
an operational amplifier circuit having a non-inverting input terminal and an inverting input terminal to which a source voltage of the second MOS transistor and a preset voltage are supplied respectively, and having an output terminal connected in common to the back gate of the MOS transistor and to a back gate of the second MOS transistor.

8. The buffer circuit according to claim 1, further comprising:
a second MOS transistor; and
an operational amplifier circuit having a non-inverting input terminal and an inverting input terminal to which a source voltage of the second MOS transistor and a preset voltage are supplied respectively,
the MOS transistor having a gate connected via a first capacitor to an input terminal for receiving an input signal, and also connected via a first resistor to a bias terminal supplied with a bias voltage,
the second MOS transistor having a gate connected via a second resistor to the bias terminal,
the MOS transistor having the back gate connected via a second capacitor to the input terminal, and also connected via a third resistor to an output terminal of the operational amplifier circuit,
the source of the MOS transistor being used as an output node of the buffer circuit, and
the second MOS transistor having a back gate connected via a fourth resistor to the output terminal of the operational amplifier circuit.
